(19) United States
(12) Patent Application Publication
(10) Pub. No.: US 2015/0261898 A1
(43) Pub. Date: Sep. 17, 2015

(54) SYSTEMS, METHODS, AND MEDIA FOR ENERGY USAGE SIMULATORS

(71) Applicant: ARIZONA BOARD OF REGENTS, FOR AND ON BEHALF OF, ARIZONA STATE UNIVERSITY, Scottsdale, AZ (US)

(72) Inventors: Sandeep Gupta, Phoenix, AZ (US); Georgios Varsamopoulos, Tempe, AZ (US)

(21) Appl. No.: 14/416,544

(22) PCT Filed: Jul. 23, 2013
(86) PCT No.: PCT/US2013/051727

§ 371 Date: May 20, 2015

Related U.S. Application Data
(60) Provisional application No. 61/676,602, filed on Jul. 27, 2012.
(60) Provisional application No. 61/674,708, filed on Jul. 23, 2012.

(51) Int. Cl. G06F 17/50; G01R 21/04; F28D 19/00; G06F 9/455

(52) U.S. Cl. CPC G06F 17/5009; G06F 9/455; G01R 21/04; F28D 19/00

(57) ABSTRACT

Systems, methods, and media for an energy usage simulator are provided. In some embodiments, systems for an energy usage simulator are provided, the systems comprising: at least one hardware processor that is configured to: perform computational fluid dynamics simulations on an environment based on a description of the environment; generate a heat recirculation matrix (HRM) based on the computational fluid dynamics simulations; generate a resource utilization matrix (RUM) based at least in part on the HRM and a power curve; generate a power consumption distribution vector based at least in part on the HRM and the RUM; and generate a thermal map of the environment based at least in part on the power consumption distribution vector.

### CROSS REFERENCE TO RELATED APPLICATION

This application claims the benefit of U.S. Provisional Patent Application No. 61/676,602, filed Jun. 27, 2012, and U.S. Provisional Patent Application No. 61/674,708, filed Jul. 23, 2012, each of which is hereby incorporated by reference herein in its entirety.

### STATEMENT REGARDING GOVERNMENT FUNDED RESEARCH

This invention was made with government support under CRI project No. 0855277 and grant No. 0834797 awarded by the National Science Foundation. The government has certain rights in the invention.

### BACKGROUND

Data centers are large and ever expanding users of energy. With the increased usage of Internet and social media, cloud-based services are extending the existing data center roles and are predicted to increase the usage of data centers to unprecedented levels. Data centers already are one of the leading consumers of energy in the US, having increased their energy usage by 56% since 2005, and the new services they will provide only ensure that they will continue to grow. However, a considerable portion of the energy cost of running a data center is avoidable through an intelligent understanding and management of the cyber-physical interactions within them. The idle power usage of equipment is largely beyond the control of data center owners. Considerable savings can be attained by efficiently designing the physical environment, management architectures, and controlling the cyber-physical interactions manifested through heat exchanges between components in the data center.

Energy-efficient data center design and management has been a problem of increasing importance in the last decade due to its potential to save billions of dollars in energy costs. There are several physical (energy) performance metrics, e.g., max power usage, power usage effectiveness (PUE), data center compute efficiency (DCcE), energy reuse efficiency (ERE), and computational performance metrics, e.g., throughput, response delay, turn-around time. However, the state of the art in design and evaluation of data centers requires designers to be expertly familiar with a prohibitively large number of domain-specific design tools which require user intervention in each step of the design process. This is due to the lack of a holistic data center design tool that can capture both cyber and physical performance.

Accordingly, new mechanisms for energy usage simulators are desired.

### SUMMARY

Methods, systems, and media for an energy usage simulator are provided. In some embodiments, systems for an energy usage simulator are provided, the systems comprising: at least one hardware processor that is configured to: perform computational fluid dynamics simulations on an environment based on a description of the environment; generate a heat recirculation matrix (HRM) based on the computational fluid dynamics simulations; generate a resource utilization matrix (RUM) based at least in part on the HRM and a power curve; generate a power consumption distribution vector based at least in part on the HRM and the RUM; and generate a thermal map of the environment based at least in part on the power consumption distribution vector.

In some embodiments, methods for an energy usage simulator are provided, the methods comprising: performing, using a hardware processor, computational fluid dynamics simulations on an environment based on a description of the environment; generating, using the hardware processor, a heat recirculation matrix (HRM) based on the computational fluid dynamics simulations; generating, using the hardware processor, a resource utilization matrix (RUM) based at least in part on the HRM and a power curve; generating, using the hardware processor, a power consumption distribution vector based at least in part on the HRM and the RUM; and generating, using the hardware processor, a thermal map of the environment based at least in part on the power consumption distribution vector.

In some embodiments, non-transitory computer-readable media containing computer-executable instructions that, when executed by a processor, cause the processor to perform a method for an energy usage simulator are provided, the method comprising: performing computational fluid dynamics simulations on an environment based on a description of the environment; generating a heat recirculation matrix (HRM) based on the computational fluid dynamics simulations; generating a resource utilization matrix (RUM) based at least in part on the HRM and a power curve; generating a power consumption distribution vector based at least in part on the HRM and the RUM; and generating a thermal map of the environment based at least in part on the power consumption distribution vector.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 is a block diagram of an example of a data center in accordance with some embodiments.

FIG. 2 is a block diagram of an example of a system for energy usage simulations in accordance with some embodiments.

FIG. 3 is a block diagram of an example of a computational fluid dynamics simulator module in accordance with some embodiments.

FIG. 4 is an example of a heat recirculation matrix in accordance with some embodiments.

FIG. 5 is a block diagram of an example of a cyber-physical simulation engine module in accordance with some embodiments.

FIG. 6 is a block diagram of an example of a resource manager module in accordance with some embodiments.

FIG. 7 is an example of an input file for describing a data center in accordance with some embodiments.

FIG. 8 is an example of an organizing collection structure in accordance with some embodiments.

FIG. 9 is an example of corner points of internal objects being projected to a reference wall of a data center in accordance with some embodiments.

FIG. 10 is an example of lines of a reference wall being extruded up to points marking the edge of objects in a data center in accordance with some embodiments.

### DETAILED DESCRIPTION

In some embodiments, mechanisms (e.g., including systems, methods, media, etc.) for energy usage simulators are provided. The mechanisms can be used in various applications. For example, the mechanisms can be used to analyze energy efficiency for a data center by studying and testing different data center geometrics, workload characteristics, platform power management schemes, scheduling algorithms, data center configurations, etc. In some embodiments, the mechanisms can perform multiple simulations for multiple configurations of a data center in an iterative manner to select a desired configuration.

In some embodiments, the mechanisms can be implemented by an architecture comprising a computational fluid dynamics (CFD) simulator module, an Input Output Manager (IOM) module, a Resource Manager (RM) module, a server database, and a Cyber-Physical Simulation Engine (CPSE) module.

In some embodiments, the CFD simulator module can receive an input file containing descriptions of a data center and generate a heat recirculation profile for the data center based on the input file. For example, the CFD simulator module can parse the input file (e.g., an XML file, etc.) and extract geometric information of the data center from the parsed input file. The CFD simulator module can then perform one or more CFD simulations based on the geometric information and generate a heat recirculation matrix (HRM) for the data center based on the results of the CFD simulations. In some embodiments, the CFD simulator module can generate multiple HRMs (e.g., an array of HRMs) for different configurations of the data center.

In some embodiments, the IOM module can manage inputs and outputs for the CFD simulator module, the CPSE module, and the RM module. For example, the IOM module can serve as a user interface for the other modules and receive suitable user inputs. In a more particular example, the user inputs can include a job trace defining the characteristics of the workloads supplied to the data center. In another more particular example, the user inputs can include one or more Service Level Agreements (SLAs) that provide requirements for response times, deadlines, etc. In yet another more particular example, the user inputs can include one or more management schemes, such as workload management schemes, power management schemes, cooling management schemes, etc.

As another example, the IOM module can store a set of HRMs for a data center. In a more particular example, the IOM module can store an array of HRMs for different active server sets. In some embodiments, the IOM module can select a suitable HRM for the data center based on feedback information transmitted from the RM module.

In some embodiments, the RM module can make various management decisions based on physical behavior of the data center. For example, the RM module can perform workload management by scheduling and placing suitable workload for the data center. In a more particular example, the RM module can decide when and where (e.g., on what servers) to serve a particular workload using a rank based algorithm, a control based algorithm, an optimization based algorithm, etc. As another example, the RM module can perform power management by controlling the power mode of one or more components of the data center. More particularly, for example, the RM module can save energy or achieve a particular power capping goal by controlling one or more components of the data center to operate in lower power states. As yet another example, the RM module can perform cooling management and determine the thermostat settings of one or more cooling units in the data center. In some embodiments, the RM module can generate a Resource Utilization Matrix (RUM) including information about active server sets (e.g., sets of servers that are not in a sleep state), workload schedule (e.g., start times of the jobs for a particular workload), power modes, etc. In some embodiments, a RUM can be generated for each time epoch or event associated with a workload and can be sent to the CPSE module.

In some embodiments, the CPSE module can estimate the physical behavior of the data center in response to one or more management decisions made by the RM module. For example, for each management decision, the CPSE module can calculate the response time, a power consumption distribution vector, a thermal map of the data center, etc. corresponding to the management decision. In some embodiments, the CPSE module can output a log file including the response time, the power consumption distribution vector, the thermal map, etc. The log file can then be transmitted to the RM module as feedback.

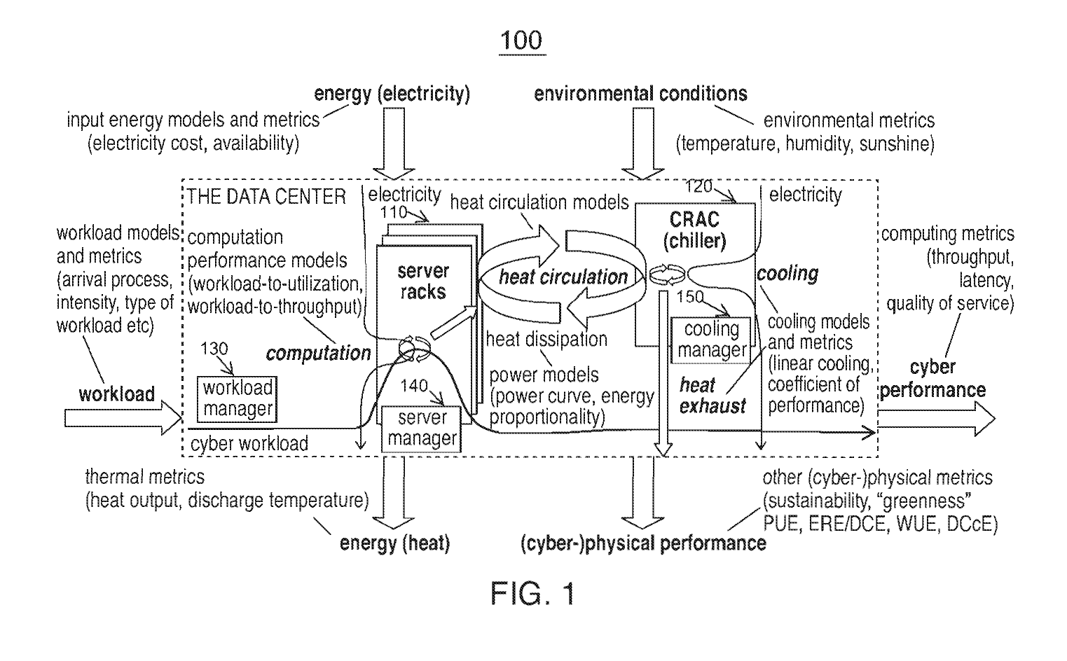

Turning to FIG. 1, a generalized block diagram of an example 100 of a data center in accordance with some embodiments is shown. In some embodiments, data center 100 can be a cyber-physical system including multiple cyber components (e.g., servers, jobs, scheduling models, etc.) and physical components (e.g., Computer Room Air Conditioning (CRAC) units, air flow pattern, etc.) that can interact with each other.

As illustrated, data center 100 can include multiple servers 110, one or more chillers 120, one or more workload managing module 130, one or more server managing modules 140, one or more cooling managing modules 150, and/or any other suitable components.

In some embodiments, servers 110 can be connected to each other through one or more suitable networks and share memory, hardware processors, network bandwidth, computational load, and/or other resources. In some embodiments, each of servers 110 can process various types of workloads as they arrive at data center 100. For example, each of servers 110 can process high-performance computing workload (HPC), such as weather prediction, etc. Alternatively or additionally, each of servers 100 can process transactional service (TS) workload, such as bank database transactions, etc.

When processing workload and/or performing other suitable functions, servers 110 may consume electricity and emit heat to data center 100. In some embodiments, the heat may be removed by air-cooling solutions. For example, hot air generated by servers 110 may travel around the data center's environment and eventually enter one or more of chillers 120. In some embodiments, chillers 120 can include one or more computer room air conditioners (CRACs) and/or heat ventilation air conditioners (HVACs). In some embodiments, cooling managing module 150 can control chillers 120 to supply cool air to data center 100.

As shown, workload managing module 130 can make decisions about scheduling and/or dispatching workload arrived at data center 100. For example, workload managing module 130 can determine when and where (e.g., on what servers) the arrived workload should be assigned.

In some embodiments, server managing module 140 can control the power consumed by each of servers 110. For example, server managing module 140 can control one or more of servers 110 to operate in suitable power states, such as frequency states (e.g., p-states), sleep scheduling states (e.g., c-states), duty cycling or throttling states (e.g., t-states), etc.

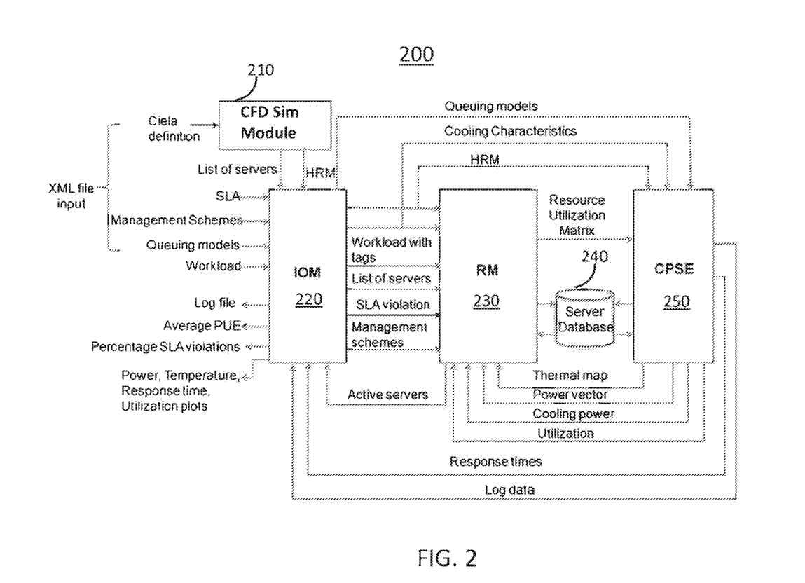

Turning to FIG. 2, an example of a block diagram of a system for providing energy usage simulations that can be used to model such cyber-physical interactions in a data center in accordance with some embodiments is shown. As illustrated, system 200 can include a computational fluid dynamics (CFD) simulator module 210, an Input Output Manager (IOM) module 220, a Resource Manager (RM) module 230, a server database 240, and a Cyber-Physical Simulation Engine (CPSE) module 250.

CFD simulator module 210 can provide users (e.g., data center designers, algorithm developers, data center operators, etc.) with one or more physical models (e.g., heat recirculation models) for online resource allocation and experimenting with a variety of physical designs of a data center. In some embodiments, the physical models can include one or more heat recirculation matrixes (HRMs) that can be used to analyze heat circulation and heat recirculation within the data center, evaluate the performance of a physical design of the data center, etc.

In some embodiments, the physical models can be generated in any suitable manner. For example, CFD simulator module 210 can generate geometric information about the data center, process the geometric information, and generate a physical model that can be used to estimate the thermal behavior of a data center. Additionally or alternatively, multiple physical models (e.g., an array of physical models) can be generated for various configurations of the data center.

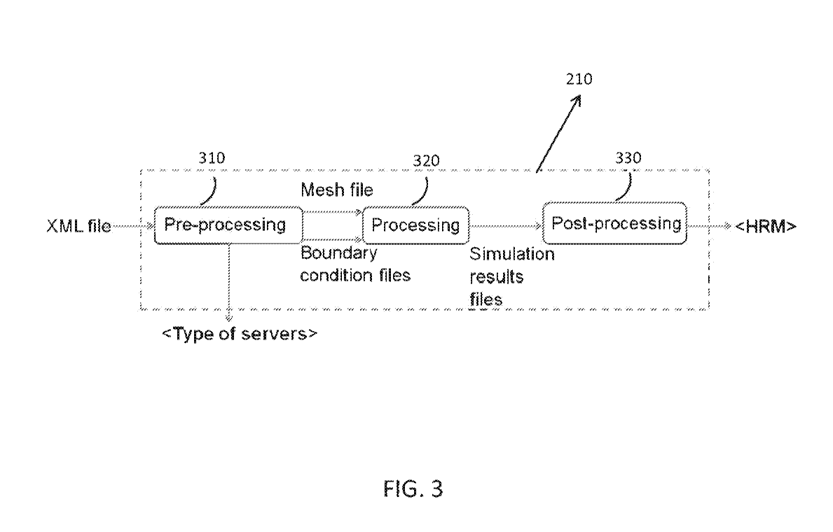

In a more particular example, as illustrated in FIG. 3, CFD simulator module 210 can generate an HRM for the data center based on an input file that contains descriptions of the data center. As shown, CFD simulator module 210 can include a pre-processing sub-module 310, a processing sub-module 320, a post-processing sub-module 306, and/or any other suitable components.

Pre-processing sub-module 310 can generate a geometry of the data center. The geometry of the data center can be generated in any suitable manner. For example, as illustrated in FIG. 3, pre-processing sub-module 310 can receive an input file containing information about the geometry of the data center. Pre-processing sub-module 310 can then parse the input file and generate the geometry of the data center and/or boundary conditions based on the parsed input file. In some embodiments, pre-processing sub-module 310 can generate one or more mesh files including information about the geometry of the data center. Additionally or alternatively, pre-processing sub-module 310 can generate one or more boundary condition files based on the boundary conditions. In some embodiments, the mesh files and the boundary condition files can be transmitted to processing sub-module 320.

In some embodiments, pre-processing sub-module 310 can obtain information about the types of the servers in the data center based on the input file. For example, pre-processing sub-module 310 can extract an array of strings that define the models of the servers from the input file. In some embodiments, the information about the types of the servers can be transmitted to IOM module 220 and/or RM module 230.

In some embodiments, the input file can have any suitable format. For example, the input file can be an Extensible Markup Language (XML) file that contains descriptions of the data center. In a more particular example, the input file can be written in the Computer Infrastructure Engineering LAnguage (CIELA) that is a high level XML-based specification language.

In some embodiments, the input file can include any suitable information relating to the geometry of the data center, and other features of the data center and/or the components of the data center. For example, the input file can include information about equipment configuration relating to the data center, such as stacking of servers, chassis power consumption, air flow rate, etc. As another example, the input file can include information about the physical layout of the data center, such as presence of raised floors, vented ceilings, perforated tiles and vents, etc.

In some embodiments, the input file can provide information about geometry or other characteristics of the data center by description. For example, each component of the data center can be described by dimensions, power, thermal characteristics, etc.

Additionally or alternatively, the input file can provide such information by name of the data center and/or the components of the data center. For example, the input file can include information about the make and model of the data center and/or a component of the data center. Pre-processing sub-module 310 can then convert such information into physical descriptions of the data center and/or the components of the data center based on a model library. In some embodiments, the model library may be implemented as a separate XML file. In some embodiments, this model library may be implemented by use of an RDBMS (Relational Data Base Management System).

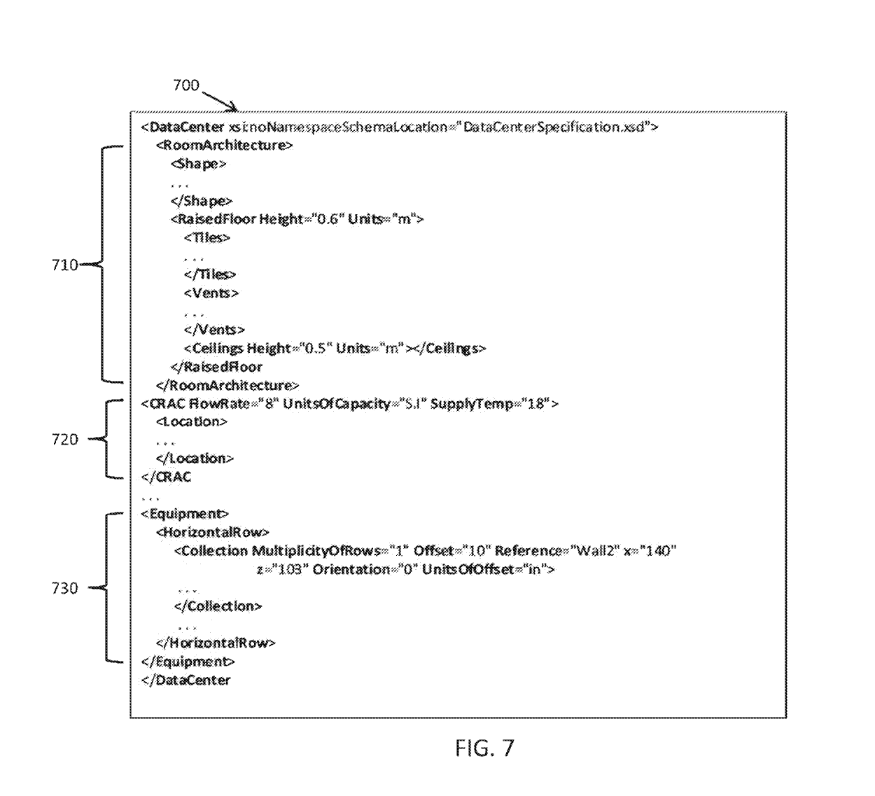

In a more particular example, as shown in FIG. 7, an input file 700 (e.g., a CIELA file) can include one or more room architecture components 710, one or more Computer Room Air Conditioner (CRAC) components 720, one or more equipment components 730, and other suitable components.

As illustrated, room architecture component 710 can include information about one or more objects of the data center, such as a raised floor, vented ceiling, perforated tiles, hot air return vents, etc. that are located in a data center room. In some embodiments, such information can be provided in input file 700 in any suitable manner. For example, the shape of the room can be defined with reference to one or multiple walls within the room. More particularly, for example, the shape of the room can be described in terms of wall length, height, orientation, etc. In some embodiments, the orientation of the first wall is the reference (x-axis) and the subsequent wall orientation is with respect to the previous wall mentioned.

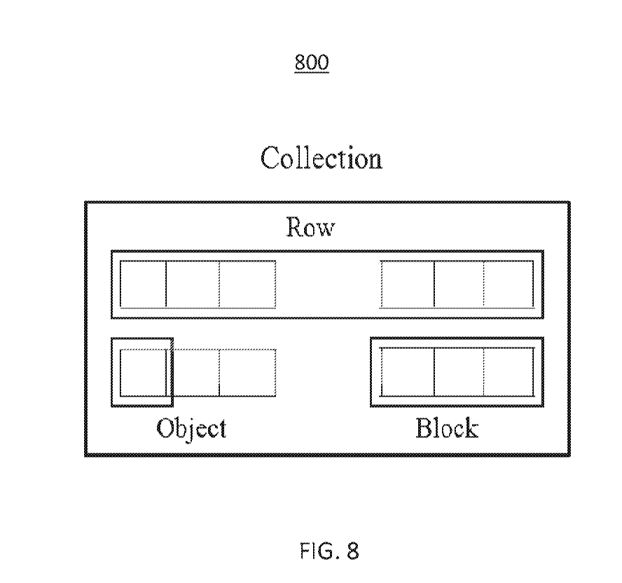

In a more particular example, as illustrated in FIG. 8, a homogeneous collection of objects can form a block and different blocks can be separated by an offset. In some embodiments, a set of blocks with the same orientation can form a row and a set of rows can form a collection.

Referring back to FIG. 7, CRAC component 720 can include information about one or more CRACs located in the data center. For example, such information can include the positions of the CRACs, the type of each CRAC, the flow rate of each CRAC, etc. In some embodiments, the position of each CRAC can be defined with response to a named reference wall.

Equipment component 730 can include information about one or more objects of the data center, such as tiles, vents, racks, etc. For example, the objects can be organized using the collection structure discussed in connection with FIG. 8. In some embodiments, the data center can include one or more blade servers. In such an example, the user can additionally specify the server model, air flow, and a RackOpening field which defines the direction of air flow through the chassis as being toward or away from a reference wall as 0 or 1, respectively.

Referring back to FIG. 3, in response to receiving the input file, pre-processing sub-module 310 can parse the input file in some embodiments. The parsing can be performed in any suitable manner. For example, pre-processing sub-module 310 can extract one or more points defined in input file 312. In a more particular example, descriptions of multiple points at the corners of the data center and/or all of the internal objects in the data center can be extracted from the input file.

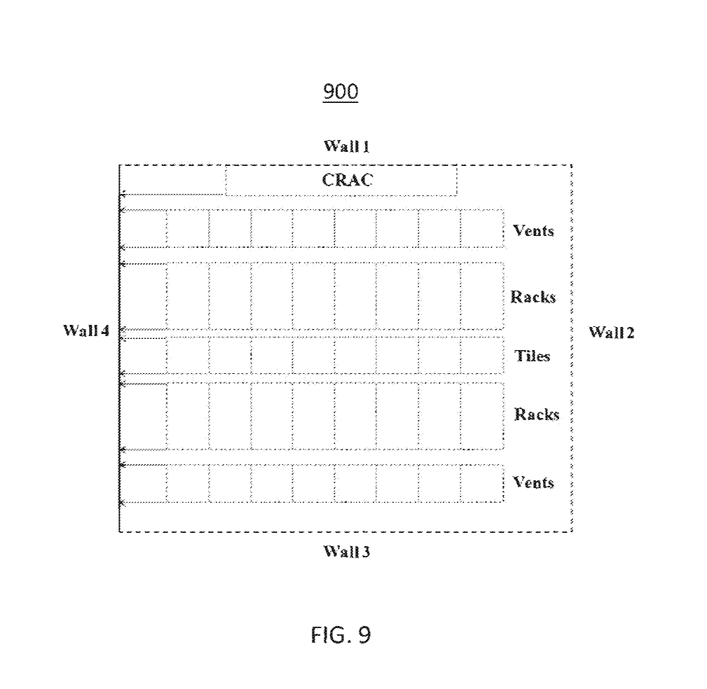

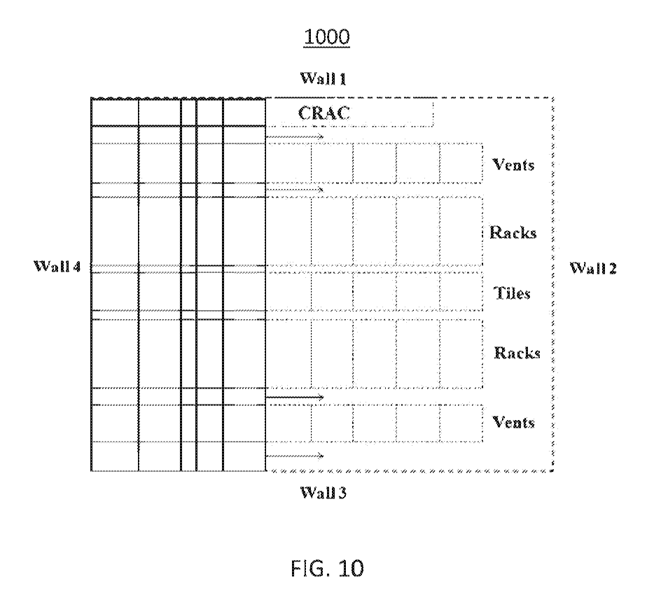

In some embodiments, pre-processing sub-module 310 can generate the geometry of the data center based on the parsed input file. For example, in the example where input file 312 specifies the points at the corners of the room and all the internal objects, pre-processing sub-module 310 can project the corner points of internal objects to the reference wall of the data center room. In some embodiments, pre-processing sub-module 310 can also connect the points on the reference wall by lines. In a more particular example, the corner points of the internal objects can be projected as shown by arrows in FIG. 9. Next, as shown in FIG. 10, the points can then be connected by lines and these lines are then “extruded” up to the points marking the edge of objects to generate a set of surfaces. These surfaces are extruded along the height of the room to generate three dimensional volumes.

Referring back to FIG. 3, pre-processing sub-module 310 can generate a geometry file including information about the geometry of the data center. In some embodiments, the geometry file can be converted into one or more mesh files. The conversion can be performed in any suitable manner. For example, the conversion can be performed using GMSH, which is described in Geuzaine, C. and Remacle, J.-F., “Gmsh: A 3-D finite element mesh generator with built-in pre- and post-processing facilities,” International Journal for Numerical Methods in Engineering 79, 11, 2009, which is hereby incorporated by reference herein in its entirety.

In some embodiments, pre-processing sub-module 310 can also generate one or more files including the boundary conditions. The boundary condition file(s) can be generated in any suitable manner. For example, in some embodiments, a boundary condition file can be provided by user inputs (e.g., though IOM module 220 of FIG. 2).

In some embodiments, processing sub-module 320 can perform one or more CFD simulations on a particular data center. For example, processing sub-module 320 can receive mesh file 314 and/or boundary condition files 316 produced by pre-processing sub-module 310. Processing sub-module 320 can then perform a series of CFD simulations on the data center based on the mesh files and/or the boundary condition files. In some embodiments, processing sub-module 320 can produce one or more simulation results files including the results of the CFD simulations and supply the simulation results files to post-processing sub-module 330.

In some embodiments, the CFD simulations can be performed in any suitable manner. For example, a suitable number of CFD simulations can be carried out to generate an uncalibrated HRM. In some embodiments, in each of the CFD simulations, a chassis in the data center can run at a suitable power state, such as a peak power state, an idle power state, etc. In a more particular example, the CFD simulations can be carried out with each chassis running at peak power while others run at idle power. Additionally or alternatively, a simulation can be carried out where all chassis are running at idle power. In such an example, a total of n+1 CFD simulations (where n is the number of chassis) can be carried out.

As another example, a suitable number of simulations can be performed to calibrate the results of one or more previous simulations. In a more particular example, the results of the n+1 simulations described above can be calibrated by m additional CFD simulations. In some embodiments, the value of m can be determined by a user.

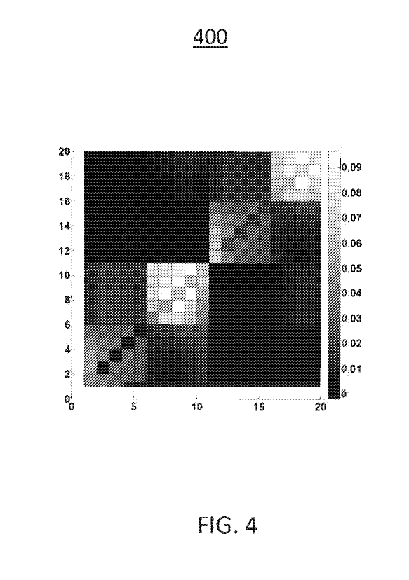

Post-processing sub-module 330 can generate one or more HRMs for the data center. The HRMs can be generated in any suitable manner. For example, post-processing sub-module 330 can generate an HRM based on the results of multiple CFD simulations (e.g., such as the simulation results files produced by processing sub-module 320). In a more particular example, where n+1 CFD simulations are performed as described above, post-processing sub-modules can generate an HRM using cross interface profiling techniques. More particularly, for example, as shown in FIG. 4, a gray-scale-coded HRM can be generated in some embodiments.

As another example, post-processing sub-module 330 can calibrate an HRM and generate a calibrated HRM. More particularly, for example, post-processing sub-module 330 can predict a rise in server inlet temperature based on the HRM and measure one or more temperatures based on the results of one or more CFD simulations. Post-processing sub-module 330 can then compare the predicted temperature rise and the measured temperatures and calibrate the HRM based on the comparison.

In a more particular example, where an HRM is derived from n+1 simulations as described above, the server inlet temperature rise can be predicted as follows:

Tᵢₙ^{pred}=Tₛᵤₚ+Dp (1)

where, D=((K−A^{T}K)⁻¹−K⁻¹), (2)

where K is the matrix of heat capacity of air through each chassis; A is the HRM; Tᵢₙ^{pred} is a vector representing the predicted air-inlet temperatures at the servers; Tₛᵤₚ is a vector representing the temperature supplied by the CRAC; and p is a vector of power drawn from each server.

In some embodiments, to calibrate the D matrix, a suitable number of CFD simulations can be carried out using utilizations representative of common workloads. For example, a simulation temperature rise T_{cfd}^{rise} can be recorded for each of the CFD simulations. For each simulation temperature rise measured by the CFD simulations, a T_{cfd}^{rise} can be recorded in some embodiments. Corresponding rise in temperatures, T_{pred}^{rise}, can then be predicted using the current D matrix. In a more particular example, the calibrated D^{new} matrix can be obtained as follows:

$${d}_{ij}^{new} = {d}_{ij} + \frac{{T}_{pred}^{rise} - {T}_{cfd}^{rise}}{{T}_{pred}^{rise} \times n} \times {\sum }_{j = 1}^{n} {d}_{ij} \qquad ( 3 )$$

Referring back to FIG. 2, CPSE module 250 can predict the physical behavior of a data center in response to potential resource management decisions made by RM module 230 and provide feedback to RM module 230. For example, for a particular management decision (e.g., a workload management decision, a power management decision, a cooling management decision, a combined management decision, etc.), CPSE module 250 can generate job response times, server power consumption, CRAC power consumption, a thermal map of the data center, etc.

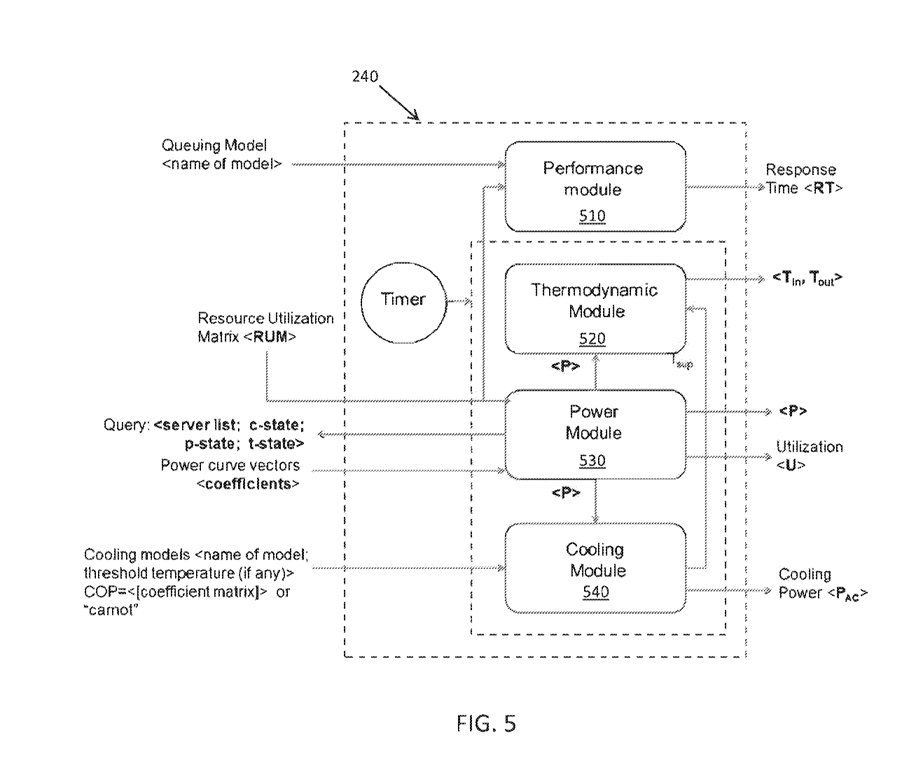

In some embodiments, CPSE module 250 can include multiple sub-modules that can calculate response times, server power consumption, and other characteristics of the data center based on one or more performance models, power curves, etc. For example, as shown in FIG. 5, CPSE module 250 can include a performance sub-module 510, a thermodynamic sub-module 520, a power sub-module 530, a cooling sub-module 540, and/or other suitable components.

As illustrated, performance sub-module 510 can calculate response times for a particular management decision based on a suitable performance model. In some embodiments, the performance model can be selected by a user using IOM model 220 of FIG. 2.

In some embodiments, any suitable performance model can be used to calculate response times for various types of jobs, such as HPC workloads, TS workloads, etc. For example, an event based performance model can be used to calculate response times for HPC workloads. In a more particular example, the event based performance model may define a set of events that can include one or more of arrival of new jobs (job arrival), beginning of job execution (job start), end of job execution (job completion), etc. The response times can then be calculated based on inter event interval (e.g., event period) that can represent the time between two consecutive job start and completion events.

As another example, a time discretized performance model can be used to calculate response times for TS workloads. In a more particular example, the time discretized performance model can divide the arrival of jobs into a set of blocks of time. In some embodiments, each of the blocks of time can represent a summary view of the job performance within the block. In another more particular example, the time discretized performance model can also define one or more job performance metrics, such as average arrival frequency, average service time, etc. In some embodiments, the job performance metrics can be computed in any suitable manner. For example, the job performance metrics can be computed based on a probability distribution (e.g., Poisson) of job characteristic in one or more blocks of time.

In some embodiments, performance sub-module 510 can measure computational performance of one or more servers in the data center using suitable metrics, such as throughput, response delay time, turn-around time, etc. For example, the value of a metric can be determined based on the utilization level of a server. In a more particular example, the performance metrics can be obtained using a suitable analytical and/or numerical method that can be defined as follows:

performance_metric=f_{method}(utilization_level). (4)

In some embodiments, performance module 510 can receive a Resource Utilization Matrix (RUM) including information about the utilization levels of one or more servers in the data center (e.g., such as a RUM supplied by RM module 230 of FIG. 2 as described below). Performance module 510 can then predict the computational performance based on the received RUM. In a more particular example, the RUM can be supplied to a suitable analytical or numerical method to yield the Computational Performance Matrix (CPM):

CPM=f_{method}(RUM). (5)

In some embodiments, power sub-module 530 can generate a power consumption distribution vector indicating the power consumed by one or more servers in the data center. The power consumption distribution vector can then be transmitted to thermodynamic sub-module 520 and/or cooling sub-module 540.

The power consumption distribution vector can be generated in any suitable manner. For example, power sub-module 530 can calculate the power consumed by a particular server for a particular utilization based on a power curve associated with the particular server. In a more particular example, power sub-module 530 can request the power curve based on the model of the particular server. In some embodiments, power sub-module 530 can receive a Resource Utilization Matrix (RUM) (e.g., supplied by RM module 230 of FIG. 2 as described below) containing any suitable information about one or more servers corresponding to a particular time epoch, such as the server model of each server, the Advanced Configuration and Power Interface controlled sleep states (c-states), frequency states (p-states), throttling states (t-states), the utilization of each chassis, the cooling schedule of CRAC units, etc. Power sub-module 530 can then query a server database to retrieve a coefficient matrix of the power curve associated with the particular server model at a given state.

In some embodiments, any suitable power curve can be used to perform power management. For example, a power curve can reflect power usage that is a non-linear function of utilization. In a more particular example, the power curve can be modeled as configurable 11-element arrays of power consumption at 10% increments, with linear interpolation between points. In some embodiments, these models can be measured directly from a server's under-utilization. Alternatively or additionally, these models can be derived from existing benchmarks. In another more particular example, the power curve can use a linear function to perform experiments with hypothetically energy-proportional servers.

In some embodiments, there may be an alternative energy source or an energy storage unit. These units may be simulated by a special power sub-module called energy source sub-module. The power consumption can be recorded, which can in turn be used to compute power efficiency metrics.

In some embodiments, a change in server utilization can cause the server power consumption to change to a new value after a time delay. The time delay can depend on the type of server being used and any other suitable factor(s). In some embodiments, when a server utilization changes, the new power consumption value can be stored in a queue for the respective delay period and can then be dispatched after the delay period has completed.

In some embodiments, thermodynamic sub-module 520 can generate a thermal map of the data center. The thermal map can then be sent to RM module 230 (FIG. 2) in a feedback loop.

The thermal map can include any suitable information about heat circulation and/or heat recirculation within the data center. For example, the thermal map can contain one or more inlet temperatures and/or outlet temperatures corresponding to a particular time epoch. In a more particular example, the inlet temperatures and the outlet temperatures corresponding to a current time epoch, can be expressed as:

Tᵢₙ={Tᵢₙ¹,Tᵢₙ², . . . ,Tᵢₙⁿ}, and

Tₒᵤₜ={Tₒᵤₜ¹,Tₒᵤₜ², . . . ,Tₒᵤₜⁿ}, respectively.

In some embodiments, the outlet temperature and inlet temperature of each chassis can be calculated using equations 6 and 7, respectively:

Tₒᵤₜ=Tₛᵤₚ+(K−A^{T}K)⁻¹p, (6)

Tᵢₙ=Tₒᵤₜ−K⁻¹p, (7)

where Tₛᵤₚ is the CRAC supply temperature, K is the matrix of heat capacity of air through each chassis and A is the HRM.

In some embodiments, cooling sub-module 540 can calculate a cooling power for the data center. As described above in connection with FIG. 3, an HRM can be used to predict the temperature rise of a server's inlets due to heat recirculation (e.g., “Dp” in equation 1). A data centers' cooling power can be affected by the temperature rise. In other words, cooling power can depend on the CRAC's Coefficient of Performance (CoP) that can represent the ratio of heat removed from the CRAC to the electric energy input to the CRAC. In some embodiments, the CRAC's COP can be a super linear and monotonically increasing function of the supplied temperature Tₛᵤₚ. The highest CRAC supplied temperature can be limited by the servers' redline temperature. Therefore, Tₛᵤₚ can be limited to:

Tₛᵤₚ=T^{red}−max(Dp), (8)

where T^{red} is the redline temperature of a server, and max(Dp) is the maximum permitted temperature rise of the server. The cooling power, denoted by p^{AC}, can be written as:

$${P}^{AC} = \frac{{p}^{comp}}{CoP ( {T}^{red} - max ( Dp ) )} , \qquad ( 9 )$$

where p^{comp} denotes the total computing power.

In some embodiments, power sub-module 530 may compute the overall energy consumed by the data center by integrating the computing power consumption and the cooling power consumption over the simulation time. In some embodiments, power sub-module 530 may compute the physical performance metrics (PUE) as follows:

PUE=P_{computing}+Pₙₒₙ_{_{—}}_{computing}/P_{computing} (10)

In some embodiments, cooling sub-model 540 can implement various cooling models. For example, a dynamic cooling model corresponding to multiple modes of operation can be used. In a more particular example, the dynamic cooling model can include multiple modes of operation that can be triggered by suitable CRAC inlet temperatures, such as a high mode, a low mode, etc. Cooling sub-module 540 can switch between the high mode and the low mode based on the CRAC inlet temperature and extract a suitable amount of heat when operating in each mode. More particularly, for example, cooling sub-module 540 can compare the CRAC inlet temperature (T_{SCRAC}ⁱⁿ) with a higher threshold temperature (T_{high}^{th}) and/or a lower threshold temperature (T_{low}^{th}). In response to determining that T_{CRAC}ⁱⁿ crosses T_{high}^{th}, cooling sub-module 540 can operate in the high mode and extract p^{high} amount of heat. Alternatively, in response to determining that T_{CRAC}ⁱⁿ crosses T_{low}^{th}, cooling sub-module 540 can operate in the low mode and extract p^{low} amount of heat. In some embodiments, any suitable threshold temperatures can be used to calculate the cooling power. For example, the threshold temperatures can be selected by a user (e.g. through the IOM module as discussed below). In some embodiment, switching between modes can incur a time delay, during which the CRAC can operate in the previous mode. In some embodiments, the time delay can be defined by a user through IOM module 220 of FIG. 2.

As another example, cooling sub-module 540 can implement a constant cooling model. In a more particular example, the constant cooling model can assume that a supply temperature, Tₛᵤₚ, is constant. In such an example, the outlet temperature can match a predetermined value (e.g., a value specified by the user).

As yet another example, an instantaneous cooling model can be implemented by cooling sub-module 540. In a more particular example, RM module 230 can adjust a cooling load based on a total heat generated by one or more components of the data center and redline temperatures of the components.

In some embodiments, CPSE module 250 can generate a log file including one or more power-model parameters, thermodynamic-model parameters, performance-model parameters, cooling model parameters, etc. The log file can then be transmitted to RM module 230 and/or IOM module 220 as feedback.

Referring back to FIG. 2, RM module 230 can make various management decisions for the data center, such as decisions about workload management, cooling management, power management, etc. Such decisions can be made in any suitable manner. For example, RM module 230 can make such decisions based on physical behavior (e.g., thermal behavior, air flow within the data center, etc.) of the data center. In a more particular example, as described above in connection with FIG. 5, CPSE module 250 can predict the physical impact of one or more management decisions made by RM module 230 and generate feedback containing information about such predictions. RM module 230 can then make management decisions based on the feedback generated by CPSE module 250.

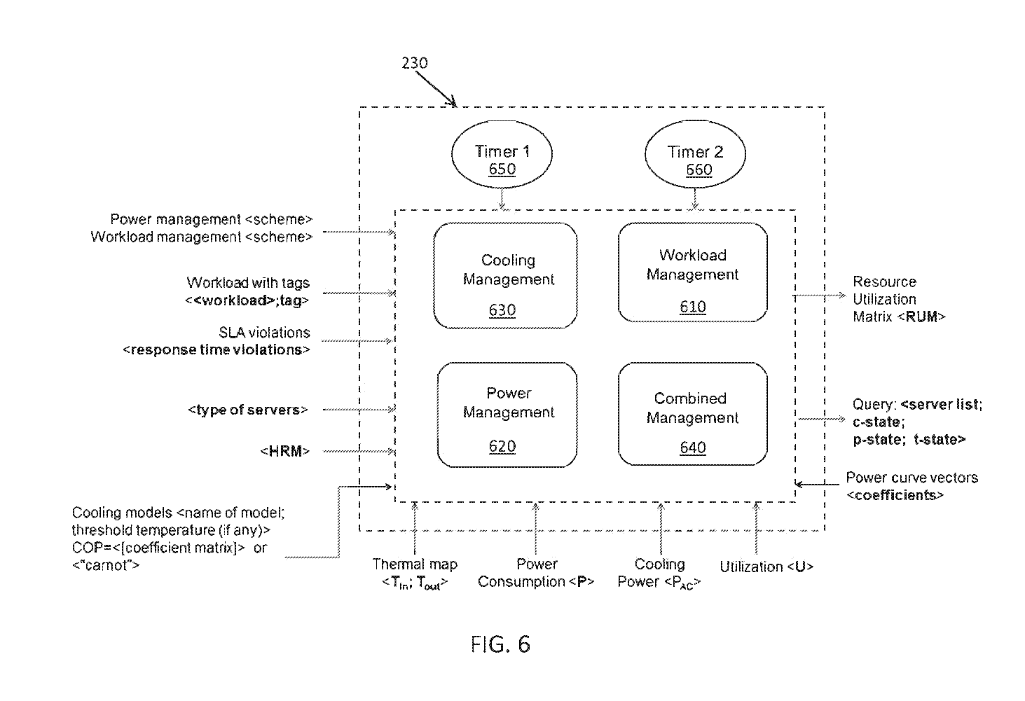

In some embodiments, RM module 230 can include one or more sub-modules, each of which can perform one or more of cooling management, workload management, power management, combined management (e.g., coordinated workload, power, and cooling management), etc. For example, as illustrated in FIG. 6, RM module 230 can include a workload management sub-module 610, a power management sub-module 620, a cooling management sub-module 630, a combined management sub-module 640, timers 650 and 660, and/or any other suitable components.

In some embodiments, the use of these sub-modules can be triggered in any suitable manner. For example, the use of these sub-modules can be triggered by HPC job arrival events for HPC data centers. In a more particular example, RM module 230 can listen for HPC job arrival event from IOM module 220.

As another example, the use of these sub-modules can be triggered by timeout events for Internet or transactional data centers (IDC). More particularly, for example, RM module 230 can make management decisions at different granularities of time. In a more particular example, long-time decisions can be made on the active server set for peak load during coarsely granular long time epochs. In another more particular example, short-time decisions can be made on percentage load distribution to the active servers based on the average load during the finely granular short time intervals.

In some embodiments, RM module 230 can make such time based decisions using timers 650 and 660. In a more particular example, when timer 650 or 660 expires, RM module 230 can trigger the long-time decision making process and the short-time decision making process, respectively. Such multi-tier resource management can be used in some embodiments to address: (i) different resources in the system having different state transition delays—for instance, processors may require more wake-up time for higher c-state numbers; and (ii) the variation of transactional workload such as Web traffic being very high, unpredictable, exhibiting hourly/minute cyclic behavior, etc.

Workload management sub-module 610 can determine when (e.g., scheduling) and where (e.g., on what servers) to place workload. In some embodiments, such determination can be made for various types of the workloads and/or events in a suitable manner. For example, in response to one or more HPC job arrival events, workload management sub-module 610 can schedule and/or place specific jobs for one or more HPC workloads. As another example, workload management sub-module 610 can distribute suitable requests (e.g., making short-time decisions) among servers for IDCs.

In some embodiments, workload management sub-module 610 can make workload management decisions using suitable algorithms. For example, a rank based algorithm (e.g., a thermal-aware placement algorithm, an energy-aware placement algorithm, etc.) can be used to make such decisions. In a more particular example, workload management sub-module 610 can assign ranks to the servers in the data center and place (or distribute) workload based on the ranks of the servers.

As another example, workload management sub-module 610 can make workload management decisions using a control based algorithm that can control a system in a closed loop to get a desired response. In a more particular example, workload management sub-module 610 can track performance parameters (e.g., response time) of jobs and then control the workload arrival rate to get a desired response time.

As yet another example, workload management sub-module 610 can make workload management decisions using an optimization based algorithm. In a more particular example, the optimization based algorithm can involve solving an optimization problem and/or selecting a desired solution from a set of feasible solutions to schedule and place workload, and/or to select an active server set.

Power management sub-module 620 can control the power mode of a system and/or components of the system in some embodiments. For example, when the workload is low, power management sub-module 620 can control one or more servers to operate in a low power state to save energy and/or achieve a particular power capping goal.

In some embodiments, for example, power management can include sleep state transition and dynamic server provisioning. For example, power management sub-module 620 can put one or more servers to sleep. As another example, power management sub-module 620 can power one or more servers down as workload varies.

In some embodiments, for example, power management can be achieved through CPU power management. In a more particular example, power management sub-module 620 can conduct c-state management by controlling CPU sleep state transition. In another more particular example, power management sub-module 620 can conduct p-state management (e.g., dynamic voltage and frequency scaling (DVFS)). More particularly, for example, in a specific power state, the CPU frequency can be scaled to save energy.

In some embodiments, power management sub-module 620 can perform management using any suitable power management algorithms. For example, power management sub-module 620 can make power management decisions using a control based algorithm that can control a system in a closed loop to get a desired response. In a more particular example, power management sub-module 620 can track performance parameters (e.g., response time) of jobs and control the workload arrival rate to get a desired response time.

As yet another example, power management sub-module 620 can make power management decisions using an optimization based algorithm. In a more particular example, the optimization based algorithm can involve solving an optimization problem and/or selecting a desired solution from a set of feasible solutions to transit sleep state, provision dynamic server, manage CPU power, etc.

Cooling management sub-module 630 can control the thermostat settings of the cooling units in some embodiments. Any suitable approach for controlling the thermostat settings can be used in some embodiments. For example, cooling management sub-module 630 can adopt a static approach by using constant pre-set thermostat settings. As another example, cooling management sub-module 630 can adopt a dynamic approach by scheduling thermostat settings based on various events.

In some embodiments, combined management sub-module 640 can integrate decision making of workload, power, and/or cooling management. Combined management can be ranking based, control based, and/or optimization based in some embodiments. For control-based and/or optimization-based management, control and optimization variables (respectively) can increase for a combined sub-module. For ranking-based combined management, the ranking mechanism can take into account the interplay between workload, power, and cooling.

In some embodiments, RM module 230 can output information relating to an active server set (e.g., the set of servers which are not in a sleep state), workload schedule (e.g., job start times), workload placement (e.g., assignment of jobs for HPC workload and percentage distribution of requests for transactional workload), power modes (e.g., clock frequency of the server platforms in the active server set), and/or cooling schedule (e.g., the highest thermostat settings of cooling units permitted by each chassis while avoiding redlining). Depending on this cooling schedule, the CPSE can set the CRAC thermostat to the lowest value.

In some embodiments, RM module 230 can generate a Resource Utilization Matrix (RUM) by compiling multiple outputs relating to the active server set, workload schedule, workload placement, power modes, cooling schedule, etc. For example, the RUM can include a chassis list containing information relating to the names of the chassis in a given format. As another example, the RUM can include a utilization element that contains information about the percentage of utilization. As yet another example, the RUM can include the c-state, the p-state, the t-state are the sleep, frequency and throttling states (respectively), the workload tag describes the type of workload (e.g., HPC or transactional), the server type is the model of the server(s), and the cooling schedule is the schedule used by the CPSE to set the CRAC thermostat, of each chassis for the particular time epoch/event.

Turning back to FIG. 2, IOM module 220 can manage inputs and/or outputs of one or more components of system 200, such as RM module 230, CPSE module 250, etc. For example, IOM module 220 can serve as a user interface for system 200 and receive various user inputs that can be used to perform energy usage simulations for a data center. In a more particular example, IOM module 220 can receive one or more job traces that can define the characteristics of a workload supplied to the data center, such as the arrival rate of the workload, the type of the workload, etc. In some embodiments, for example, IOM module 220 can associate one or more workload tags with a workload to identify the type of the workload (e.g., HPC workloads, transactional workloads, etc.) and transmit the workload tags to RM module 230 and/or CPSE module 250. In such an example, RM module 230 and/or CPSE module 250 can select a suitable simulation algorithm based on the workload tags. In a more particular example, an event based simulation algorithm can be selected for HPC workloads. In another more particular example, a time discretized simulation algorithm can be selected for transactional workloads.

In another more particular example, IOM module 220 can receive one or more inputs relating to Service Level Agreements (SLAs), such as SLA requirements defining the requirements of SLAs with customers of the data center. In some embodiments, the SLA requirements can include one or more reference response times. IOM module 220 can detect SLA violations by comparing the response times output by CPSE module 250 with the reference response times. More particularly, for example, an SLA violation can be detected when a response time supplied from CPSE module 250 exceeds a reference response time. In some embodiments, IOM module 220 can also report the SLA violations to RM module 230.

In another more particular example, IOM module 220 can receive one or more inputs including information about one or more management schemes selected by a user. Examples of the management schemes can include one or more of power management schemes, workload management schemes, cooling characteristic schemes, etc. In some embodiments, IOM module 220 can transmit information about the selected management schemes to RM module 230. RM module 230 can then perform workload management, power management, cooling management, combined management, etc. based on the inputs (e.g., as described above in connection with FIG. 6).

In yet another more particular example, IOM module 220 can receive one or more inputs containing information about one or more queuing models that can be used to analyze the response time of a server, such as an M/M/n queuing model, a GI/G/1 queuing model, etc.

As another example, IOM module 220 can store an array of HRMs for a data center for different active server sets and provide an HRM when needed. In a more particular example, IOM module 220 can select an appropriate HRM based on the feedback transmitted from RM module 230 and/or CPSE module 250. IOM module 220 can then provide the selected HRM to RM module 230 and/or CPSE module 250.

In some embodiments, system 200 can include a server database 240. Server database 240 can include any suitable circuitry that is capable of storing power curves, redline temperatures of different server models corresponding to various power states (e.g., c-states, e-states, t-states, etc.), and other suitable data. For example, server database 240 can include a hard drive, a solid state storage device, a removable storage device, or any other suitable storage device.

In some embodiments, each of the modules of FIG. 2 and each of the sub-modules of FIGS. 3, 5, and 6 can be implemented in one or more hardware processors, such as digital signal processors (DSPs), microprocessors, controllers, FPGAs, or any suitable general or special purpose processors.

In some embodiments, a graphical front user interface (GUI) which will allow a user to interact with the software can be provided. Capabilities of the GUI may include uploading of XML documents, starting, stopping and managing of simulations, gathering of results, etc. In some embodiments, this GUI may be implemented through a Web/HTML interface.

In some embodiments, simultaneous execution of multiple simulations can be provided. In those embodiments, a cluster management architecture to dispatch and collect simulation tasks can be provided.

In some embodiments, installations may feature an accounting component in which users have to provide login credentials to access the tool. An accounting component may be used to protect and secure files and work on a per-account basis and may disallow access to users on files that do not belong to their accounts.

In accordance with some embodiments, any suitable hardware can be used to implement the mechanisms described herein. For example, in some embodiments, a general purpose device such as a computer or a special purpose device such as a client, a server, etc. can be used to perform the functions of the various mechanisms described herein. For example, in some embodiments, such a general purpose device or a special purpose device can be used to provide the mechanisms illustrated in FIG. 2. Any of these general or special purpose devices can include any suitable components such as a hardware processor (which can be a microprocessor, digital signal processor, a controller, etc.), memory, communication interfaces, display controllers, input devices, etc.

In some embodiments, any suitable computer readable media can be used for storing instructions for performing the processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although the invention has been described and illustrated in the foregoing illustrative embodiments, it is understood that the present disclosure has been made only by way of example, and that numerous changes in the details of implementation of the invention can be made without departing from the spirit and scope of the invention, which is only limited by the claims which follow. Features of the disclosed embodiments can be combined and rearranged in various ways.

1. A system for an energy usage simulator, comprising:
at least one hardware processor that is configured to:
perform computational fluid dynamics simulations on an environment based on a description of the environment;
generate a heat recirculation matrix (HRM) based on the computational fluid dynamics simulations;
generate a resource utilization matrix (RUM) based at least in part on the HRM and a power curve;
generate a power consumption distribution vector based at least in part on the HRM and the RUM; and
generate a thermal map of the environment based at least in part on the power consumption distribution vector.

2. The system of claim 1, wherein the environment is a data center.

3. The system of claim 1, wherein the description of the environment is received as an XML file.

4. (canceled)

5. The system of claim 1, wherein the resource utilization matrix indicates active equipment in the environment.

6. The system of claim 1, wherein the hardware processor is further configured to generate a feedback file based at least in part on the power consumption distribution vector and the thermal map.

7. A method for an energy usage simulator, comprising:
performing, using a hardware processor, computational fluid dynamics simulations on an environment based on a description of the environment;
generating, using the hardware processor, a heat recirculation matrix (HRM) based on the computational fluid dynamics simulations;
generating, using the hardware processor, a resource utilization matrix (RUM) based at least in part on the HRM and a power curve;
generating, using the hardware processor, a power consumption distribution vector based at least in part on the HRM and the RUM; and
generating, using the hardware processor, a thermal map of the environment based at least in part on the power consumption distribution vector.

8. The method of claim 7, wherein the environment is a data center.

9. The method of claim 7, wherein the description of the environment is received as an XML file.

10. The method of claim 7, wherein the resource utilization matrix indicates active equipment in the environment.

11. The method of claim 7, further comprising generating a feedback file based at least in part on the power consumption distribution vector and the thermal map.

12. A non-transitory computer-readable medium containing computer-executable instructions that, when executed by a processor, cause the processor to perform a method for an energy usage simulator, the method comprising:
performing computational fluid dynamics simulations on an environment based on a description of the environment;
generating a heat recirculation matrix (HRM) based on the computational fluid dynamics simulations;
generating a resource utilization matrix (RUM) based at least in part on the HRM and a power curve;
generating a power consumption distribution vector based at least in part on the HRM and the RUM; and
generating a thermal map of the environment based at least in part on the power consumption distribution vector.

13. The non-transitory computer-readable medium of claim 12, wherein the environment is a data center.

14. The non-transitory computer-readable medium of claim 12, wherein the description of the environment is received as an XML file.

15. The non-transitory computer-readable medium of claim 12, wherein the resource utilization matrix indicates active equipment in the environment.

16. The non-transitory computer-readable medium of claim 12, wherein the method further comprises generating a feedback file based at least in part on the power consumption distribution vector and the thermal map.
